(19) United States
(12) Patent Application Publication
(10) Pub. No.: US 2008/0036522 A1
(43) Pub. Date: Feb. 14, 2008

(54) Level-shifting circuits and methods of level shifting

(75) Inventors: Dae-Young Chung, Seoul (KR); Sang-Kyu Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/891,332

(22) Filed: Aug. 10, 2007

(30) Foreign Application Priority Data
Aug. 11, 2006 (KR) 10-2006-0075953

(51) Int. Cl. H03L 5/00

(52) U.S. Cl. 327/333

(57) ABSTRACT

A level-shifting circuit includes a level shifter and a middle voltage generating unit. The level shifter generates a middle voltage signal by level-shifting a first signal. The middle voltage signal swings between a level of a ground voltage and a level of a middle voltage, and the first signal swings between the level of the ground voltage and a level of a first voltage. In addition, the level shifter generates a second signal by level-shifting the middle voltage signal. The second signal swings between the level of the ground voltage and a level of a second voltage. The middle voltage generating unit generates the middle voltage by receiving the second voltage and the ground voltage. Therefore, the level-shifting circuit increases an operating margin of an input voltage.

### CROSS-REFERENCE TO RELATED APPLICATIONS

This application claims priority under 35 USC §119 to Korean Patent Application No. 10-2006-0075953, filed on Aug. 11, 2006 in the Korean Intellectual Property Office (KIPO), the contents of which are incorporated herein by reference in their entirety.

### BACKGROUND OF THE INVENTION

1. Field of the Invention

The present invention relates to semiconductor devices, and more particularly to level-shifting circuits and methods of level shifting.

2. Description of the Related Art

Most semiconductor integrated circuits (ICs) include internal circuits for performing internal functions and interface circuits for interfacing with external circuits. Also, the semiconductor ICs include a power supply device for providing a power voltage to the internal circuits and the interface circuits. Most of the internal circuits use a power voltage below 1.0 V, but most of the interface circuits use a power voltage over 1.0V(e.g., 1.8V or 2.5V).

Because there is a voltage difference between the internal circuits and the interface circuits, a level shifter is required for interfacing between the internal circuits and the interface circuits.

As demand for low-power semiconductor ICs using a deep submicron process (e.g., 90 nm or 65 nm) is increasing, a level shifter that interfaces between the interface circuits using a relatively high power voltage (e.g., 1.8 V or 2.5 V) and the internal circuits using a relatively low power voltage (e.g., below 1.0 V) is required. In mobile applications, such as MPEG-1 Audio Layer 3 (MP3) players and personal digital assistants (PDAs), the power voltage of the internal circuits is lowered below 1 V to decrease power consumption. Therefore, when using a conventional level shifter, operating margins of the semiconductor ICs may decrease and operating capabilities of the semiconductor ICs may be degraded.

In the conventional level shifter, a first inverter receives a low voltage to provide the received low voltage to an input terminal of a latch, and ultimately generates an output signal that is level-shifted to a high voltage through a second inverter. When the latch receives a sufficiently high voltage (i.e., a voltage that is higher than a threshold voltage of a transistor in the latch), the latch can operate normally. Accordingly, decreasing the power voltage of the internal circuits causes a problem in that the operating margin of the latch is also decreased.

### SUMMARY OF THE INVENTION

Accordingly, embodiments of the present invention substantially obviate one or more problems associated with limitations and disadvantages of the related art.

Some example embodiments of the present invention provide a level-shifting circuit capable of increasing a margin of an input voltage.

Other example embodiments of the present invention provide a method of level shifting capable of increasing a margin of an input voltage.

According to a first aspect, the present invention is directed to a level-shifting circuit, which includes a level shifter and a middle voltage generating unit. The level shifter level-shifts a first signal to generate a middle voltage signal, the first signal swinging between a level of a ground voltage and a level of a first voltage and the middle voltage signal swinging between the level of the ground voltage and a level of a middle voltage, and level-shifts the middle voltage signal to generate a second signal, the second signal swinging between the level of the ground voltage and a level of a second voltage. The middle voltage generating unit generates the middle voltage based on the second voltage and the ground voltage.

In one embodiment, the level shifter includes a first level-shifting unit and a second level-shifting unit. The first level-shifting unit may generate the middle voltage signal based on the first signal. The second level-shifting unit may generate the second signal based on the middle voltage signal. The level of the first voltage may be lower than that of the middle voltage, and the level of the middle voltage may be lower than that of the second voltage.

The first level-shifting unit may include at least one buffer operated by the middle voltage.

In one embodiment, the first level-shifting unit includes a first inverter and a second inverter. The first inverter may generate an inverted signal having a level of the middle voltage or the ground voltage according to the first signal. The inverted signal corresponds to an inverted middle voltage signal. The second inverter may generate the middle voltage signal having a level of the middle voltage or the ground voltage according to the inverted signal.

The second level-shifting unit may include a buffer operated by the second voltage.

The buffer may include a latch. The latch may receive the middle voltage signal and an inverted signal, the inverted signal corresponding to an inverted middle voltage signal.

The second level-shifting unit may include a first n-type metal-oxide semiconductor (NMOS) transistor, a second NMOS transistor, a first p-type MOS (PMOS) transistor and a second PMOS transistor. The first NMOS transistor may have a gate receiving the middle voltage signal, and a source to which the ground voltage is applied. The second NMOS transistor may have a gate receiving the inverted signal, and a source to which the ground voltage is applied. The first PMOS transistor may have a source to which the second voltage is applied, a gate coupled to a drain of the second NMOS transistor, and a drain coupled to a drain of the first NMOS transistor. The second PMOS transistor may have a source to which the second voltage is applied, a gate coupled to the drain of the first NMOS transistor, and a drain coupled to the drain of the second NMOS transistor.

The middle voltage generating unit may include a plurality of loads for dividing the second voltage to generate the middle voltage. The loads may include at least one diode-connected transistor.

The middle voltage generating unit may include at least two diode-connected transistors that are coupled in series between the second voltage and the ground voltage. The middle voltage generating unit may output the middle voltage, the middle voltage corresponding to a voltage between the diode-connected transistors.

The level-shifting circuit may further include an output buffer unit. The output buffer unit may buffer the second signal to output the buffered second signal.

The output buffer unit may include an inverter operated by the second voltage.

According to another aspect, the present invention is directed to a level-shifting circuit, which includes a level shifter and a middle voltage generating unit. The level shifter level-shifts a first signal to generate at least one middle voltage signal, the first signal swinging between a level of a ground voltage and a level of a first voltage and each of the at least one middle voltage signals swinging between the level of the ground voltage and a level of at least one middle voltage, and level-shifts the at least one middle voltage signal to generate a second signal, the second signal swinging between the level of the ground voltage and a level of a second voltage. The middle voltage generating unit generates each of the at least one middle voltages based on the second voltage and the ground voltage.

According to another aspect, the present invention is directed to a method of level shifting, which includes generating a middle voltage signal by level-shifting a first signal, the first signal swinging between a level of a ground voltage and a level of a first voltage and the middle voltage signal swinging between the level of the ground voltage and a level of a middle voltage; generating a second signal by level-shifting the middle voltage signal, the second signal swinging between the level of the ground voltage and a level of a second voltage; and generating the middle voltage by receiving the second voltage and the ground voltage.

The level of the first voltage may be lower than that of the middle voltage, and the level of the middle voltage may be lower than that of the second voltage.

Generating the second signal may include differentially amplifying the middle voltage signal and an inverted signal, the inverted signal corresponding to an inverted middle voltage signal.

Generating the middle voltage may include dividing the second voltage using a plurality of loads for voltage division.

The method of level shifting may further include buffering the second signal to output the buffered second signal.

According to another aspect, the present invention is directed to a method of level shifting, which includes generating at least one middle voltage signal by level-shifting a first signal, the first signal swinging between a level of a ground voltage and a level of a first voltage and each of the at least one middle voltage signals swinging between the level of the ground voltage and a level of at least one middle voltage; generating a second signal by level-shifting the at least one middle voltage signal, the second signal swinging between the level of the ground voltage and a level of a second voltage; and generating each of the at least one middle voltages by receiving the second voltage and the ground voltage.

The present invention increases an operating margin of an input voltage.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 is a block diagram illustrating a level-shifting circuit according to an example embodiment of the present invention.

FIG. 2 is a graph illustrating operating voltages of the level-shifting circuit in FIG. 1.

FIG. 3 is a circuit diagram illustrating a level-shifting circuit according to one example embodiment of the present invention.

FIG. 4 is a circuit diagram illustrating a level-shifting circuit according to another example embodiment of the present invention.

FIG. 5 is a timing diagram illustrating simulation results of a level-shifting circuit according to an example embodiment of the present invention.

### DETAILED DESCRIPTION OF PREFERRED EMBODIMENTS

Embodiments of the present invention now will be described more fully with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

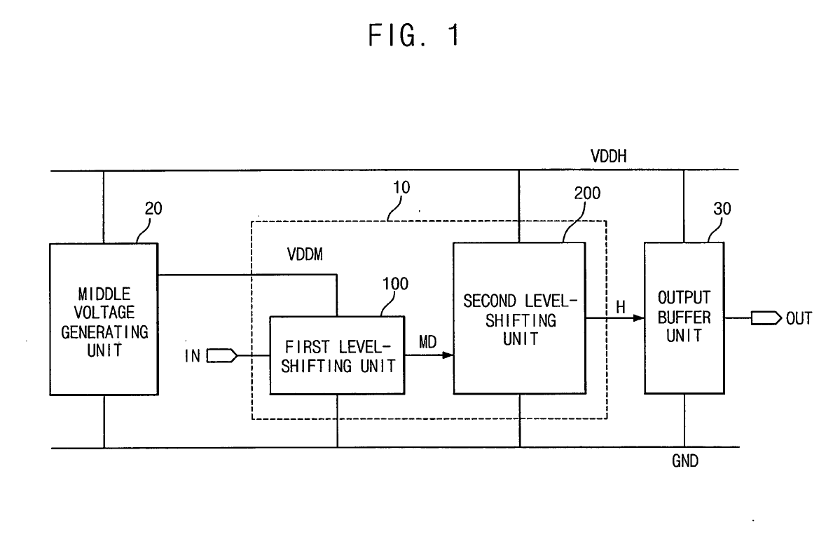

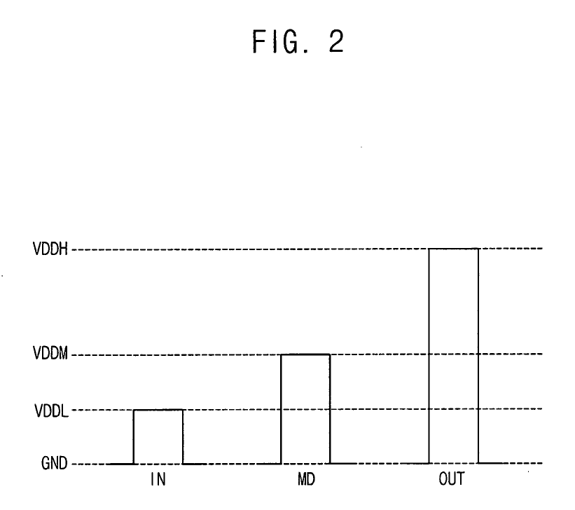

FIG. 1 is a block diagram illustrating a level-shifting circuit according to an example embodiment of the present invention, and FIG. 2 is a graph illustrating operating voltages of the level-shifting circuit in FIG. 1.

Referring to FIG. 1, the level-shifting circuit according to the invention includes a level shifter 10 and a middle voltage generating unit 20. Also, the level-shifting circuit may further include an output buffer unit 30.

Referring to FIGS. 1 and 2, a first signal IN swings between a ground voltage GND and a first voltage VDDL, and a second signal OUT swings between the ground voltage GND and a second voltage VDDH. A middle voltage signal MD swings between the ground voltage GND and a middle voltage VDDM.

The first voltage VDDL is lower than the middle voltage VDDM, and the middle voltage VDDM is lower than the second voltage VDDH. For example, the first voltage VDDL may be about 0.5 V, the middle voltage VDDM may be about 1.0 V, and the second voltage VDDH may be about 2.0 V.

Hereinafter, the operation of the level-shifting circuit will be described with reference to FIGS. 1 and 2.

The level shifter 10 includes a first level-shifting unit 100 and a second level-shifting unit 200.

The first level-shifting unit 100 operates based on the middle voltage VDDM provided from the middle voltage generating unit 20 and generates the middle voltage signal MD based on the first signal IN.

The second level-shifting unit 200 operates based on the second voltage VDDH and generates the high voltage signal H based on the middle voltage signal MD.

The middle voltage generating unit 20 includes loads for voltage division and generates the middle voltage VDDM based on the second voltage VDDH.

The output buffer unit 30 operates based on the second voltage VDDH and buffers the high voltage signal H to output the second signal OUT. In some example embodiments, the output buffer unit 30 includes at least one inverter.

The level-shifting circuit of the present invention is not limited to the configuration illustrated in FIG. 1, and the level-shifting circuit uses a plurality of middle voltage signals during level-shifting from the first signal IN to the second signal OUT. For example, the level-shifting circuit may generate a first middle voltage signal that swings between a level of a ground voltage and a level of a first middle voltage by level-shifting the first signal IN that swings between the level of the ground voltage and a level of a first voltage; and generate a second middle voltage signal that swings between the level of the ground voltage and a level of a second middle voltage by level-shifting the first middle voltage signal. The second signal OUT may be generated by level-shifting the second middle voltage signal.

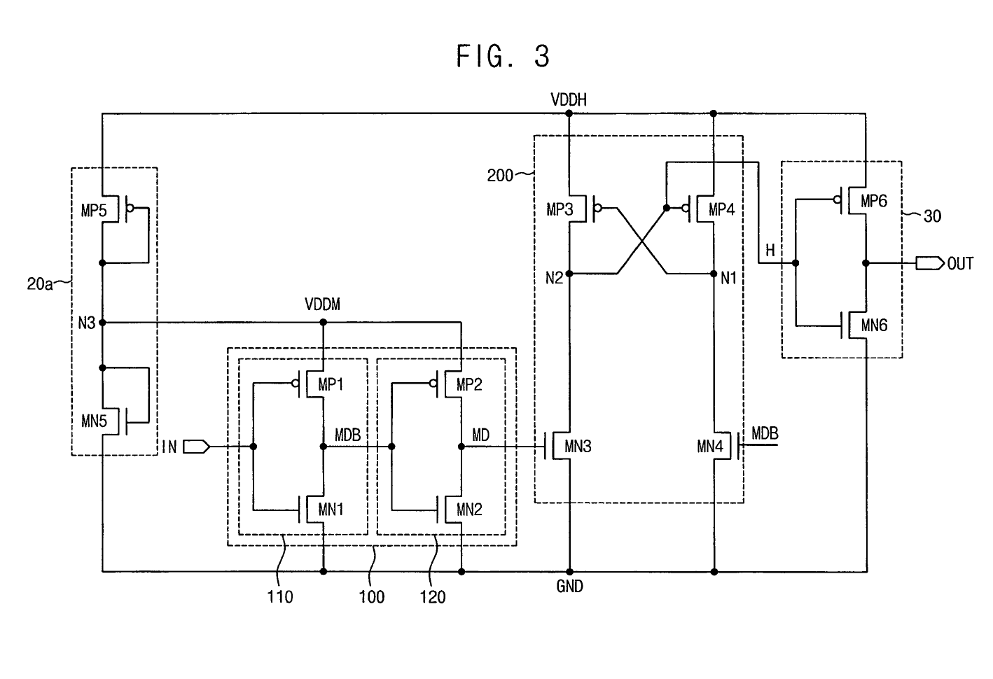

FIG. 3 is a circuit diagram illustrating a level-shifting circuit according to one example embodiment of the present invention.

Referring to FIG. 3, the level-shifting circuit according to the invention includes a first level-shifting unit 100, a second level-shifting unit 200, a middle voltage generating unit 20a and an output buffer unit 30.

The first level-shifting unit 100 may include at least one buffer that is operated by the middle voltage. For example, the buffer in the first level-shifting unit 100 may include a first inverter 110 and a second inverter 120 as illustrated in FIG. 3. The first inverter 110 includes a first p-type metal-oxide semiconductor (PMOS) transistor MP1 and a first n-type MOS (NMOS) transistor MN1. The second inverter 120 includes a second PMOS transistor MP2 and a second NMOS transistor MN2.

The first PMOS transistor MP1 includes a source to which the middle voltage VDDM is applied, and a gate receiving the first signal IN. The first NMOS transistor MN1 includes a drain coupled to a drain of the first PMOS transistor MP1, a gate receiving the first signal IN, and a source to which a ground voltage GND is applied.

When the first signal IN is at a low level, the first inverter 110 outputs the middle voltage VDDM since the first PMOS transistor MP1 is turned on and the first NMOS transistor MN1 is turned off.

On the contrary, when the first signal IN is at a high level, the first inverter 110 outputs the ground voltage GND since the first PMOS transistor MP1 is turned off and the first NMOS transistor MN1 is turned on.

The second PMOS transistor MP2 includes a source to which the middle voltage VDDM is applied, and a gate receiving an output signal MDB of the first inverter 110. The second NMOS transistor MN2 includes a drain coupled to a drain of the second PMOS transistor MP2, a gate receiving the output signal MDB of the first inverter 110, and a source to which the ground voltage GND is applied.

When the output signal MDB of the first inverter 110 is at a low level, the second inverter 120 outputs the middle voltage VDDM since the second PMOS transistor MP2 is turned on and the second NMOS transistor MN2 is turned off.

On the contrary, when the output signal MDB of the first inverter 110 is at a high level, the second inverter 120 outputs the ground voltage GND since the second PMOS transistor MP2 is turned off and the second NMOS transistor MN2 is turned on.

In some example embodiments, the first signal IN swings between a ground voltage GND and a first voltage VDDL, and the first voltage VDDL may be about 0.5 V. The middle voltage signal MD swings between the ground voltage GND and the middle voltage VDDM, and the middle voltage VDDM may be about 1.0 V.

The first voltage VDDL is high enough to turn on the first NMOS transistor MN1 or turn off the first PMOS transistor MP1. The first PMOS transistor MP1 and the first NMOS transistor MN1 have a relatively low threshold voltage so that the first voltage VDDL may be lowered to about 0.5 V. That is, the first voltage VDDL is only higher than each of the threshold voltages of the first PMOS transistor MP1, the second PMOS transistor MP2, the first NMOS transistor MN1 and the second NMOS transistor MN2.

The middle voltage VDDM has a level that does not damage the first PMOS transistor MP1, the second PMOS transistor MP2, the first NMOS transistor MN1 and the second NMOS transistor MN2. In some example embodiments, when the middle voltage VDDM is about 1 V, the first PMOS transistor MP1, the second PMOS transistor MP2, the first NMOS transistor MN1 and the second NMOS transistor MN2 are not damaged. That is, the first signal IN is level-shifted to the middle voltage signal MD through the first level-shifting unit 100.

The second level-shifting unit 200 may include a buffer that is operated by the second voltage. The buffer in the second level-shifting unit 200 may include a latch that receives the middle voltage signal and an inverted middle voltage signal. The latch may include a third PMOS transistor MP3, a fourth PMOS transistor MP4, a third NMOS transistor MN3, and a fourth NMOS transistor MN4.

The third PMOS transistor MP3 includes a source to which a second voltage VDDH is applied, a gate coupled to a first node N1, and a drain coupled to a second node N2.

The fourth PMOS transistor MP4 includes a source to which the second voltage VDDH is applied, a gate coupled to the second node N2, and a drain coupled to the first node N1.

The third NMOS transistor MN3 includes a drain coupled to the second node N2, a gate receiving the middle voltage signal MD, and a source to which the ground voltage GND is applied.

The fourth NMOS transistor MN4 includes a drain coupled to the first node N1, a gate receiving the output signal of the first inverter 110 (i.e., the inverted signal MDB of the middle voltage signal MD), and a source to which the ground voltage GND is applied.

Each of the middle voltage signal MD and the inverted signal MDB of the middle voltage signal has a voltage level that is high enough to turn on the third NMOS transistor MN3 or the fourth NMOS transistor MN4. Accordingly, the middle voltage signal MD and the inverted signal MDB may be differentially amplified. The third NMOS transistor MN3 and the fourth NMOS transistor MN4 may be implemented with dual-gate-oxide transistors. Each of the third NMOS transistor MN3 and the fourth NMOS transistor MN4 has a threshold voltage that is higher than a threshold voltage of the first PMOS transistor MP1, the second PMOS transistor MP2, the first NMOS transistor MN1 and the second NMOS transistor MN2. Therefore, the voltage that is higher than the first voltage VDDL is applied to the third NMOS transistor MN3 and the fourth NMOS transistor MN4 to turn on the third NMOS transistor MN3 and the fourth NMOS transistor MN4. In addition, the third PMOS transistor MP3, the fourth PMOS transistor MP4, a fifth PMOS transistor MP5, a sixth PMOS transistor MP6, a fifth NMOS transistor MN5 and a sixth NMOS transistor MN6 may be implemented with dual-gate-oxide transistors. That is, all other components except for the first level-shifting unit 100 may be implemented with dual-gate-oxide transistors.

Because the first signal IN is level-shifted to the middle voltage signal MD through the first level-shifting unit 100 and the middle voltage is about 1.0 V, the third NMOS transistor MN3 and the fourth NMOS transistor MN4 are turned on.

When the middle voltage signal MD has a high level and the inverted signal MDB of the middle voltage signal has a low level, the third NMOS transistor MN3 is turned on and the fourth NMOS transistor MN4 is turned off. When the third NMOS transistor MN3 is turned on, the fourth PMOS transistor MP4 is turned on. When the fourth NMOS transistor MN4 is turned off, the third PMOS transistor MP3 is turned off. Therefore, because a voltage at the second node N2 becomes substantially equal to the ground voltage GND, a high voltage signal H corresponds to the ground voltage GND.

When the middle voltage signal MD has a low level and the inverted signal MDB of the middle voltage signal has a high level, the third NMOS transistor MN3 is turned off and the fourth NMOS transistor MN4 is turned on. When the fourth NMOS transistor MN4 is turned on, the third PMOS transistor MP3 is turned on. When the third NMOS transistor MN3 is turned off, the fourth PMOS transistor MP4 is turned off. Therefore, because the voltage at the second node N2 becomes substantially equal to the second voltage VDDH, the high voltage signal H corresponds to the second voltage VDDH.

That is, the middle voltage signal MD is level-shifted to the high voltage signal H through the second level-shifting unit 200.

The middle voltage generating unit 20a may include the fifth PMOS transistor MP5 and the fifth NMOS transistor MN5. The fifth PMOS transistor MP5 may be diode-connected, and includes a source to which the second voltage VDDH is applied, and a drain coupled to a third node N3. The fifth NMOS transistor MN5 may be diode-connected, and includes a drain coupled to the third node N3, and a source to which the ground voltage GND is applied.

In some example embodiments, the fifth PMOS transistor MP5 and the fifth NMOS transistor MN5 divide the second voltage VDDH (e.g., 2.0 V) by a 1:1 ratio, and then output the middle voltage VDDM (e.g., 1.0 V) through the third node N3.

The output buffer unit 30 includes the sixth PMOS transistor MP6 and the sixth NMOS transistor MN6.

The sixth PMOS transistor MP6 includes a source to which the second voltage VDDH is applied, and a gate receiving the high voltage signal H.

The sixth NMOS transistor MN6 includes a drain coupled to the drain of the sixth PMOS transistor MP6, a gate receiving the high voltage signal H, and a source to which the ground voltage GND is applied.

The sixth PMOS transistor MP6 and the sixth NMOS transistor MN6 may be implemented with dual-gate-oxide transistors. Therefore, the second voltage VDDH is high enough to turn on the sixth NMOS transistor MN6 and turn off the sixth PMOS transistor MP6. When the high voltage signal H has a high level, the sixth PMOS transistor MP6 is turned off and the sixth NMOS transistor MN6 is turned on. Therefore, the output buffer unit 30 outputs a second signal OUT having the ground voltage GND.

When the high voltage signal H has a low level, the sixth PMOS transistor MP6 is turned on and the sixth NMOS transistor MN6 is turned off. Therefore, the output buffer unit 30 outputs the second signal OUT having the second voltage VDDH.

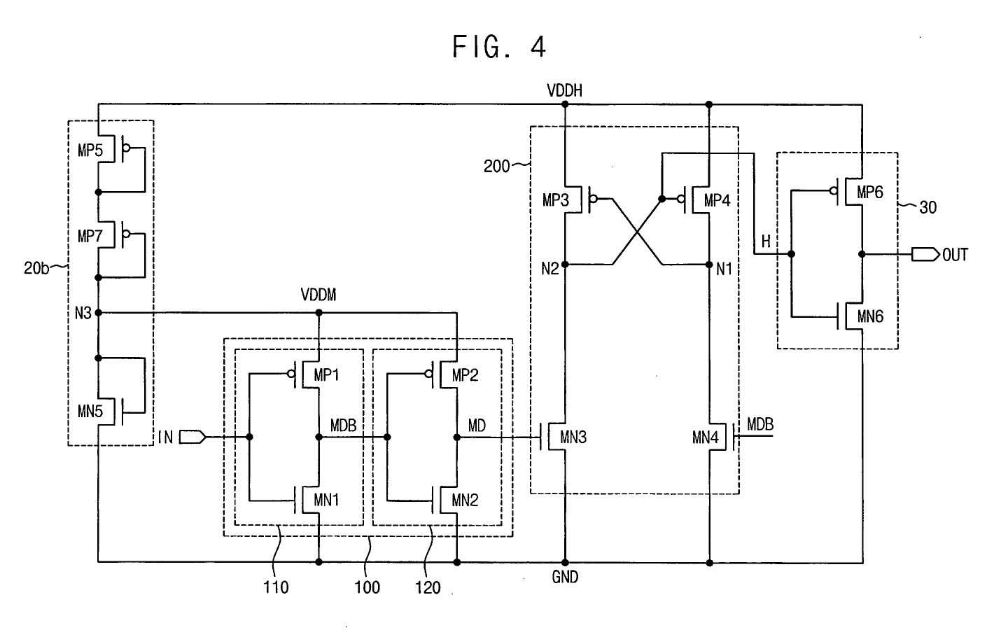

FIG. 4 is a circuit diagram illustrating a level-shifting circuit according to another example embodiment of the present invention.

Referring to FIG. 4, the level-shifting circuit according to the invention includes a first level-shifting unit 100, a second level-shifting unit 200, a middle voltage generating unit 20b and an output buffer unit 30.

Detailed descriptions of the first level-shifting unit 100, the second level-shifting unit 200 and the output buffer unit 30 are not repeated because the first level-shifting unit 100, the second level-shifting unit 200 and the output buffer unit 30 are substantially the same as those illustrated an described in connection with FIG. 3.

The first level-shifting unit 100 outputs a middle voltage signal MD by level-shifting a first signal IN. The middle voltage signal MD swings between a ground voltage GND and a middle voltage VDDM, and the first signal IN swings between the ground voltage GND and a first voltage VDDL.

The second level-shifting unit 200 outputs a high voltage signal H by level-shifting the middle voltage signal MD. The high voltage signal H swings between the ground voltage GND and a second voltage VDDH.

The middle voltage generating unit 20b may include a fifth PMOS transistor MP5, a seventh PMOS transistor MP7 and a fifth NMOS transistor MN5. The fifth PMOS transistor MP5 may be diode-connected, and includes a source to which the second voltage VDDH is applied. The seventh PMOS transistor MP7 may be diode-connected, and includes a source coupled to the drain of the fifth PMOS transistor MP5, and a drain coupled to a third node N3. The fifth NMOS transistor MN5 may be diode-connected, and includes a drain coupled to the third node N3, and a source to which the ground voltage GND is applied.

In some example embodiments, the first voltage VDDL may be about 0.5 V, and the middle voltage VDDM may be about 1.0 V, and the second voltage VDDH may be about 3.0 V.

In some example embodiments, the fifth PMOS transistor MP5, the seventh PMOS transistor MP7 and the fifth NMOS transistor MN5 divide the second voltage VDDH (i.e., 3.0 V) by a 2:1 ratio, and then output the middle voltage VDDM (i.e., 1.0 V) through the third node N3.

The output buffer unit 30 outputs the second signal OUT by buffering the high voltage signal H that is the output signal of the second level-shifting unit 200.

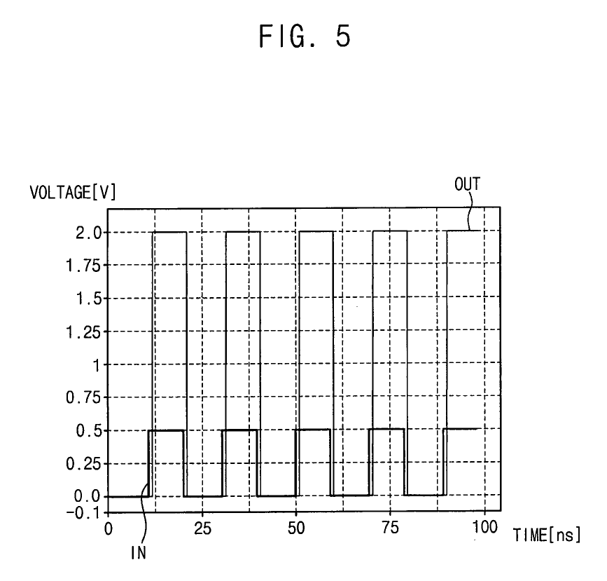

FIG. 5 is a timing diagram illustrating simulation results of a level-shifting circuit according to an example embodiment of the present invention.

In FIG. 5, the x-axis represents time and the y-axis represents a voltage.

In the conventional level shifter, an operating margin of an input voltage is about 0.9 V. However, in the level shifter of FIG. 3, although an input voltage IN is lowered to about 0.5 V, an output voltage OUT of about 2.0 V is stably outputted without any problems related to duty ratio or operating speed.

The simulation is performed five times with corner conditions of (NN, 55° C.), (SS, −55° C.), (SS, 125° C.), (FF, −55° C.) and (FF, 125° C.). The NN, SS and FF indicate process conditions of semiconductor devices. N represents a normal condition, S represents a slow condition, and F represents a fast condition.

Also, results performed in all above conditions represent that the output voltage OUT of about 2.0 V is stably outputted in spite of the input voltage IN of only about 0.5 V.

As described above, a level-shifting circuit and a method of level shifting according to example embodiments of the present invention may increase an operating margin of an input voltage.

Also, a level-shifting circuit and a method of level shifting according to example embodiments of the present invention may reduce power consumption and may improve a performance of integrated circuits.

While the example embodiments of the present invention and their advantages have been described in detail, it should be understood that various changes, substitutions and alterations may be made herein without departing from the scope of the invention.

What is claimed is:

1. A level-shifting circuit, comprising:
a level shifter configured to level-shift a first signal to generate a middle voltage signal, the first signal swinging between a level of a ground voltage and a level of a first voltage and the middle voltage signal swinging between the level of the ground voltage and a level of a middle voltage, and configured to level-shift the middle voltage signal to generate a second signal, the second signal swinging between the level of the ground voltage and a level of a second voltage; and
a middle voltage generating unit configured to generate the middle voltage based on the second voltage and the ground voltage.

2. The circuit of claim 1, wherein the level shifter comprises:
a first level-shifting unit configured to generate the middle voltage signal based on the first signal, the level of the first voltage being lower than that of the middle voltage; and
a second level-shifting unit configured to generate the second signal based on the middle voltage signal, the level of the middle voltage being lower than that of the second voltage.

3. The circuit of claim 2, wherein the first level-shifting unit includes at least one buffer that is operated by the middle voltage.

4. The circuit of claim 3, wherein the first level-shifting unit comprises:
a first inverter configured to generate an inverted signal having a level of the middle voltage or the ground voltage according to the first signal, the inverted signal corresponding to an inverted middle voltage signal; and
a second inverter configured to generate the middle voltage signal having a level of the middle voltage or the ground voltage according to the inverted signal.

5. The circuit of claim 2, wherein the second level-shifting unit includes a buffer that is operated by the second voltage.

6. The circuit of claim 5, wherein the buffer includes a latch configured to receive the middle voltage signal and an inverted signal, the inverted signal corresponding to an inverted middle voltage signal.

7. The circuit of claim 6, wherein the second level-shifting unit comprises:
a first n-type metal-oxide semiconductor (NMOS) transistor that has a gate receiving the middle voltage signal, and a source to which the ground voltage is applied;
a second NMOS transistor that has a gate receiving the inverted signal, and a source to which the ground voltage is applied;
a first p-type MOS (PMOS) transistor that has a source to which the second voltage is applied, a gate coupled to a drain of the second NMOS transistor, and a drain coupled to a drain of the first NMOS transistor; and
a second PMOS transistor that has a source to which the second voltage is applied, a gate coupled to the drain of the first NMOS transistor, and a drain coupled to the drain of the second NMOS transistor.

8. The circuit of claim 1, wherein the middle voltage generating unit includes a plurality of loads for dividing the second voltage to generate the middle voltage.

9. The circuit of claim 8, wherein the loads includes at least one diode-connected transistor.

10. The circuit of claim 8, wherein the middle voltage generating unit includes at least two diode-connected transistors that are coupled in series between the second voltage and the ground voltage, and wherein the middle voltage generating unit outputs the middle voltage, the middle voltage corresponding to a voltage between the diode-connected transistors.

11. The circuit of claim 1, further comprising an output buffer unit configured to buffer the second signal to output the buffered second signal.

12. The circuit of claim 11, wherein the output buffer unit includes an inverter that is operated by the second voltage.

13. A level-shifting circuit, comprising:
a level shifter configured to level-shift a first signal to generate at least one middle voltage signal, the first signal swinging between a level of a ground voltage and a level of a first voltage and each of the at least one middle voltage signals swinging between the level of the ground voltage and a level of at least one middle voltage, and configured to level-shift the at least one middle voltage signal to generate a second signal, the second signal swinging between the level of the ground voltage and a level of a second voltage; and
a middle voltage generating unit configured to generate each of the at least one middle voltages based on the second voltage and the ground voltage.

14. A method of level shifting, comprising:
generating a middle voltage signal by level-shifting a first signal, the first signal swinging between a level of a ground voltage and a level of a first voltage and the middle voltage signal swinging between the level of the ground voltage and a level of a middle voltage;
generating a second signal by level-shifting the middle voltage signal, the second signal swinging between the level of the ground voltage and a level of a second voltage; and
generating the middle voltage by receiving the second voltage and the ground voltage.

15. The method of claim 14, wherein the level of the first voltage is lower than that of the middle voltage and the level of the middle voltage is lower than that of the second voltage.

16. The method of claim 15, wherein generating the second signal includes differentially amplifying the middle voltage signal and an inverted signal, the inverted signal corresponding to an inverted middle voltage signal.

17. The method of claim 15, wherein generating the middle voltage includes dividing the second voltage using a plurality of loads for voltage division.

18. The method of claim 15, further comprising buffering the second signal to output the buffered second signal.

19. A method of level shifting, comprising:
generating at least one middle voltage signal by level-shifting a first signal, the first signal swinging between a level of a ground voltage and a level of a first voltage and each of the at least one middle voltage signals swinging between the level of the ground voltage and a level of at least one middle voltage;
generating a second signal by level-shifting the at least one middle voltage signal, the second signal swinging between the level of the ground voltage and a level of a second voltage; and
generating each of the at least one middle voltages by receiving the second voltage and the ground voltage.
